(19) United States
(12) Patent Application Publication
(10) Pub. No.: US 2024/0274624 A1
(43) Pub. Date: Aug. 15, 2024

(54) SEMICONDUCTOR DEVICE, DISPLAY DEVICE AND SEMICONDUCTOR INTEGRATED CIRCUIT

(71) Applicant: Japan Display Inc., Tokyo (JP)

(72) Inventor: Hirotaka HAYASHI, Tokyo (JP)

(73) Assignee: Japan Display Inc., Tokyo (JP)

(21) Appl. No.: 18/648,508

(22) Filed: Apr. 29, 2024

Related U.S. Application Data
(63) Continuation of application No. PCT/JP2022/035021, filed on Sep. 20, 2022.

(30) Foreign Application Priority Data
Nov. 15, 2021 (JP) 2021-186019

(51) Int. Cl. H01L 27/12; H01L 25/16; H01L 29/786

(52) U.S. Cl. CPC H01L 27/1255; H01L 25/167; H01L 29/78693

(57) ABSTRACT

A semiconductor device includes a first gate electrode, a first gate insulating film arranged on the first gate electrode, a semiconductor film arranged on the first gate insulating film and overlapping the first gate electrode, a first terminal in contact with the semiconductor film and electrically connected to the semiconductor film and the first gate electrode, a second terminal in contact with the semiconductor film and spaced apart from the first terminal, a second gate insulating film arranged over the semiconductor film, the first terminal and the second terminal, and a second gate electrode arranged on the second gate insulating film, overlapping the semiconductor film and electrically connected to the second terminal.

### CROSS-REFERENCE TO RELATED APPLICATIONS

This application is a Continuation of International Patent Application No. PCT/JP2022/035021, filed on Sep. 20, 2022, which claims the benefit of priority to Japanese Patent Application No. 2021-186019, filed on Nov. 15, 2021, the entire contents of each are incorporated herein by reference.

### FIELD

An embodiment of the present invention relates to a semiconductor device, a display device and a semiconductor integrated circuit.

### BACKGROUND

In recent years, a liquid crystal display device using a liquid crystal element or a display device using a light-emitting element is known as a display device. For example, the light-emitting element is a light-emitting diode (LED), a micro light-emitting diode (micro LED), or an organic electroluminescence (EL) element. In addition, the display device includes a protection circuit (semiconductor device) for protecting transistors, capacitors, resistors, and circuits including these elements from surges or electrostatic discharge (ESD). For example, the protection circuit is composed of two transistors as disclosed in Japanese laid-open patent publication No. 2019-212855 and Japanese laid-open patent publication No. 2017-147385.

### SUMMARY

A semiconductor device includes a first gate electrode, a first gate insulating film arranged on the first gate electrode, a semiconductor film arranged on the first gate insulating film and overlapping the first gate electrode, a first terminal contacted in contact with the semiconductor film and electrically connected to the semiconductor film and the first gate electrode, a second terminal in contact with the semiconductor film and spaced apart from the first terminal, a second gate insulating film arranged over the semiconductor film, the first terminal and the second terminal, and a second gate electrode arranged on the second gate insulating film, overlapping the semiconductor film and electrically connected to the second terminal.

A display device includes a semiconductor device, a display section including a plurality of pixels electrically connected to a plurality of the semiconductor devices, and a control circuit electrically connected to the plurality of pixels and controlling the plurality of pixels. The semiconductor device includes a first gate electrode, a first gate insulating film arranged on the first gate electrode, a semiconductor film arranged on the first gate insulating film and overlapping the first gate electrode, a first terminal in contact with the semiconductor film and electrically connected to the semiconductor film and the first gate electrode, a second terminal in contact with the semiconductor film and spaced apart from the first terminal, a second gate insulating film arranged over the semiconductor film, the first terminal and the second terminal, and a second gate electrode arranged on the second gate insulating film, overlapping the semiconductor film and electrically connected to the second terminal.

A semiconductor integrated circuit includes a semiconductor device and an electronic device electrically connected to the semiconductor device. The semiconductor device includes a first gate electrode, a first gate insulating film arranged on the first gate electrode, a semiconductor film arranged on the first gate insulating film and overlapping the first gate electrode, a first terminal in contact with the semiconductor film and electrically connected to the semiconductor film and the first gate electrode, a second terminal in contact with the semiconductor film and spaced apart from the first terminal, a second gate insulating film arranged over the semiconductor film, the first terminal and the second terminal, and a second gate electrode arranged on the second gate insulating film, overlapping the semiconductor film and electrically connected to the second terminal.

### BRIEF DESCRIPTION OF DRAWINGS

FIG. 1A is a plan view showing a configuration of a semiconductor device according to an embodiment of the present invention.

FIG. 1B is an end portion cross-sectional view showing a configuration of a semiconductor device according to an embodiment of the present invention.

FIG. 2A is a circuit diagram showing a circuit configuration of a semiconductor device according to an embodiment of the present invention.

FIG. 2B is a circuit diagram showing a circuit configuration of a semiconductor device according to an embodiment of the present invention.

FIG. 3 is a plan view showing a configuration of a display device according to an embodiment of the present invention.

FIG. 4 is a circuit diagram showing a configuration of a semiconductor device and a pixel circuit according to an embodiment of the present invention.

FIG. 5 is an end portion cross-sectional view showing a configuration of a semiconductor device and a pixel circuit according to an embodiment of the present invention.

FIG. 6A is a plan view showing a configuration of a semiconductor device according to a second embodiment of the present invention.

FIG. 6B is an end portion cross-sectional view showing a configuration of a semiconductor device according to a second embodiment of the present invention.

FIG. 7A is a circuit diagram showing a circuit configuration of a semiconductor device according to a second embodiment of the present invention.

FIG. 7B is a circuit diagram showing a circuit configuration of a semiconductor device according to a second embodiment of the present invention.

FIG. 8 is an end portion cross-sectional view showing a configuration of a semiconductor device and a pixel circuit according to a third embodiment of the present invention.

FIG. 9 is a plan view showing a configuration of a semiconductor integrated circuit according to a fourth embodiment of the present invention.

### DESCRIPTION OF EMBODIMENTS

For example, in order to operate a protection circuit at a desired voltage, a plurality of protection circuits may need to be connected. In addition, in order to allow a current of a magnitude corresponding to surges or ESD to flow through the protection circuit, there is a concern that the size of a transistor constituting the protection circuit needs to be increased. As a result, the circuit scale of the protection circuit may increase.

An object of an embodiment of the present invention is to provide a semiconductor device that suppresses an increase in circuit scale, and a display device including the semiconductor device.

Hereinafter, embodiments of the present invention will be described with reference to the drawings and the like. However, the present invention can be implemented in various aspects without departing from the gist thereof, and is not to be construed as being limited to the description of the embodiments exemplified below. Further, in order to make the description clearer with respect to the drawings, the width, thickness, shape, and the like of each part may be schematically represented in comparison with actual embodiments, but the schematic drawings are merely examples, and do not limit the interpretation of the present invention.

In the case where a single film is processed to form a plurality of films in the present invention, the plurality of films may have different functions and roles. However, the plurality of films is derived from a film formed as the same layer in the same process and has the same layer structure and the same material. Therefore, the plurality of films is defined as being present in the same layer.

In the embodiments of the present invention, expressions such as “above” and “below” in describing the drawings represent a relative positional relationship between a structure of interest and other structures. In the embodiments of the present invention, a direction from an insulating surface to a bank, which will be described later, is defined as “above” and the opposite direction is defined as “below” in a side view. In the embodiments of the present invention, in expressing the manner of arranging another structure on a certain structure, the term “on” shall include both the case of arranging another structure directly above a certain structure and the case of arranging another structure above a certain structure via another structure, unless otherwise specified.

Further, in the embodiments of the present invention, the expression “α includes A, B, or C,” “α includes any of A, B, or C,” and “α includes one selected from a group consisting of A, B, and C,” and the like does not exclude the case where α includes a plurality of combinations of A to C unless otherwise specified. Furthermore, these expressions do not exclude the case where α includes other elements.

Further, in each embodiment of the present invention, the same reference signs (or reference signs having numbers followed by A, B, a, b, and the like) are given to elements similar to those described above with respect to the above-mentioned figures, and detailed description thereof may be omitted as appropriate. In addition, the terms “first” and “second” appended to each element are convenience signs used to distinguish each element, and do not have any further meaning unless otherwise specified.

### First Embodiment

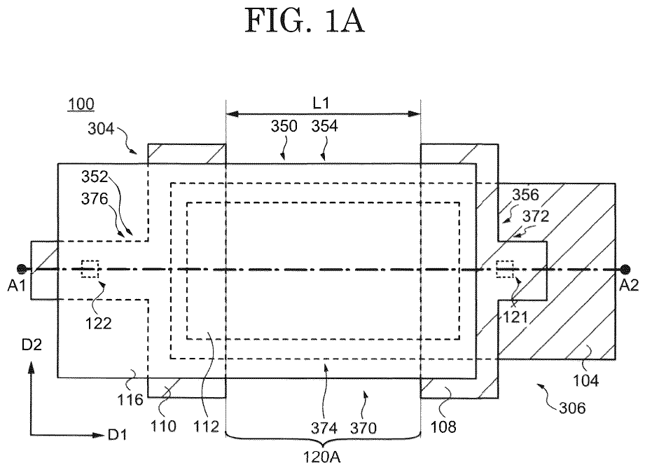

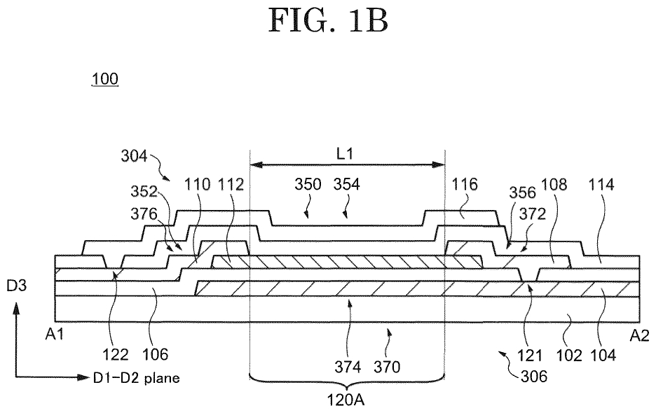

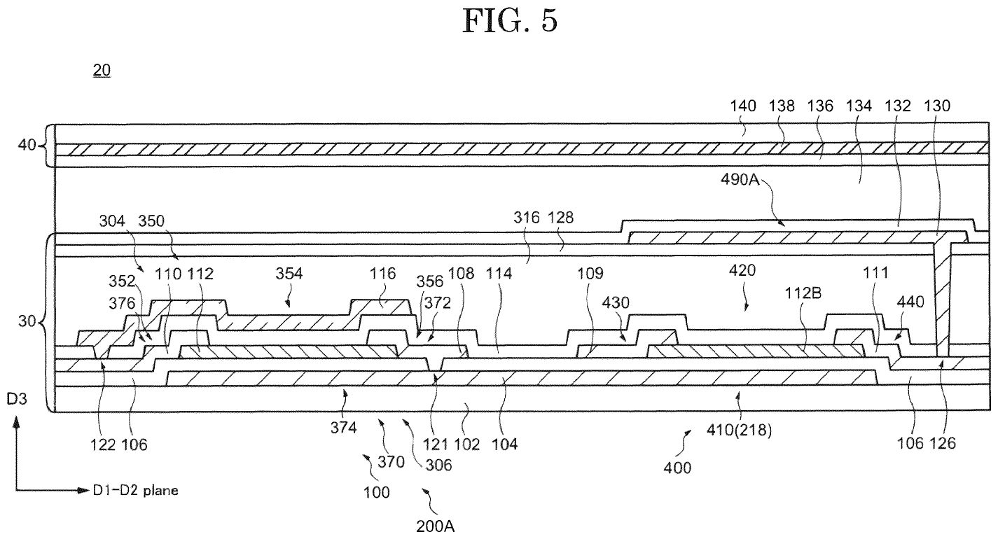

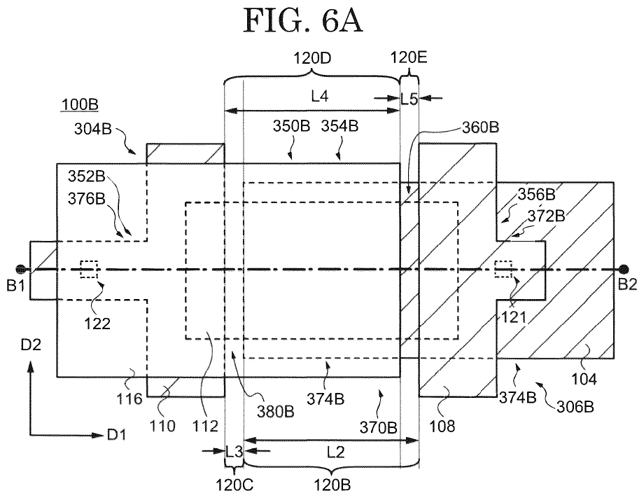

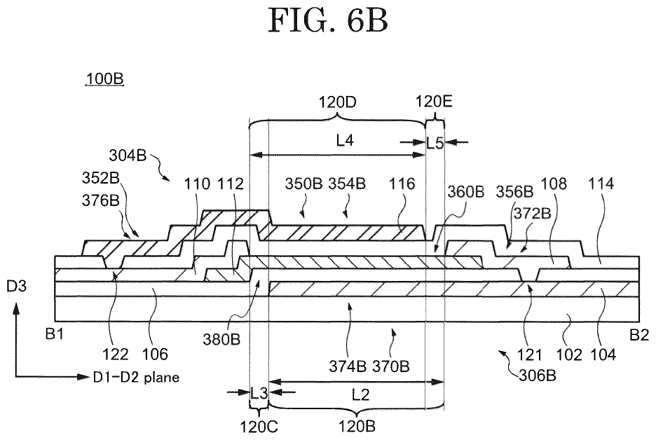

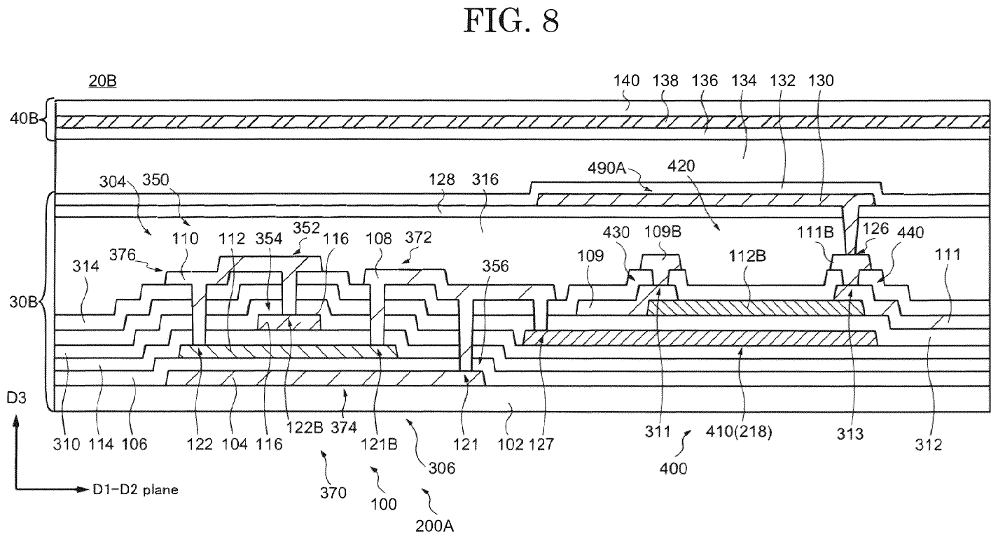

A configuration of a semiconductor device 100 according to an embodiment of the present invention and a display device 20 using the same will be described in the present embodiment. The semiconductor device 100 in the present embodiment is a protection circuit for protecting transistors, capacitors, resistors, and circuits including these elements from surges or ESD. For example, the protection circuit is a bi-directional diode. For example, the semiconductor device 100 includes a thin film transistor (TFT) as a semiconductor film 112 (FIG. 1A, FIG. 1B, FIG. 5, FIG. 6, and FIG. 8) in the present embodiment. Further, in the present embodiment, a state in which the semiconductor device 100 is viewed from a direction perpendicular to a screen (display section) is referred to as a “plan view”, and a state in which the semiconductor device 100 is cut along a plane intersecting the insulating surface or curved surface and the cut surface is viewed from a direction parallel to the screen is referred to as a “cross-sectional view”. For example, in the present embodiment, an axis parallel or substantially parallel to the long axis of a first gate electrode or a second gate electrode is defined as a first axis D1, an axis intersecting the first axis D1, and an axis parallel or substantially parallel to the short axis of the first gate electrode or the second gate electrode is defined as a second axis D2. In addition, an axis intersecting the first axis D1 and the second axis D2 and perpendicular or substantially perpendicular to a plane including the first axis D1 and the second axis D2 (D1-D2 plane) is defined as a third axis D3.

### [1-1. Configuration of Semiconductor Device 100]

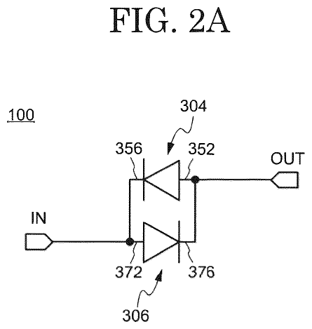

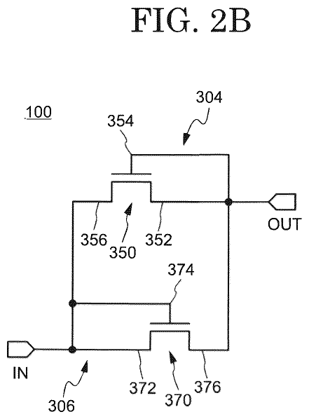

FIG. 1A is a plan view showing a configuration of the semiconductor device 100, and FIG. 1B is an end portion cross-sectional view showing part of the cross-section taken along a line A1-A2 of the semiconductor device 100 shown in FIG. 1A. FIG. 2A and FIG. 2B are circuit diagrams showing a circuit configuration of the semiconductor device 100. A configuration of the semiconductor device 100 is not limited to the configuration shown in FIG. 1A, FIG. 2A, and FIG. 2B.

The semiconductor device 100 has a first rectifier circuit 306 and a second rectifier circuit 304, as shown in FIG. 1A and FIG. 1B. Either one of the first rectifier circuit 306 or the second rectifier circuit 304 is a diode-connected first transistor, and the other of the first rectifier circuit 306 and the second rectifier circuit 304 is a diode-connected second transistor.

The first rectifier circuit 306 is a first transistor 370 and the second rectifier circuit 304 is a second transistor 350 as an example in the present embodiment. The first transistor 370 is composed of a gate electrode 374, a first gate insulating film 106, the semiconductor film 112, a first terminal 108 and a second terminal 110, and the second transistor 350 is composed of a gate electrode 354, a second gate insulating film 114, the semiconductor film 112, the first terminal 108 and the second terminal 110.

The gate electrode 374 is formed using a first gate electrode layer 104 arranged to be in contact with the upper surface of a first substrate 102. The first gate insulating film 106 is in contact with the upper surface of the first substrate 102 and the first gate electrode layer 104 and is arranged to cover the upper surface and the side surface of the gate electrode 374. The semiconductor film 112 is arranged on and in contact with the first gate insulating film 106 and is formed to overlap the gate electrode 374. The first terminal 108 is arranged so as to be in contact with part of the upper surface and side surface of the semiconductor film 112 and the upper surface of the first gate insulating film 106 and is electrically connected to the gate electrode 374 via a contact hole 121. The contact hole 121 opens the first gate insulating film 106. The second terminal 110 is in contact with part of the upper surface and side surface of the semiconductor film 112 and the upper surface of the first gate insulating film 106, is arranged apart from the first terminal 108, and is electrically connected to the gate electrode 354 via a contact hole 122. The first terminal 108 and the second terminal 110 are formed in the same layer. The contact hole 122 opens the second gate insulating film 114. The second gate insulating film 114 is arranged so as to be in contact with part of the upper surface and side surface of the semiconductor film 112, part of the upper surface and side surface of the first terminal 108, and part of the upper surface and side surface of the second terminal 110. The gate electrode 354 is formed using a second gate electrode layer 116 arranged to be in contact with the upper surface of the second gate insulating film 114. In addition, the gate electrode 354 is formed so as to overlap the semiconductor film 112 and is electrically connected to the second terminal 110 via the contact hole 122.

The arrangement of the gate electrode 374, the first gate insulating film 106, the semiconductor film 112, the first terminal 108, the second terminal 110, the second gate insulating film 114, and the gate electrode 354 may define at least one region (a first region 120A) sandwiched between the first terminal 108 and the second terminal 110 in the semiconductor film 112, in a plan view and cross-sectional view. A length of the first region 120A parallel to the first axis D1 is a length L1.

The first region 120A is a region sandwiched between the first terminal 108 and the second terminal 110 and is the region where the semiconductor film 112 overlaps the gate electrode 374 and the first gate insulating film 106. The first region 120A functions as an active region (channel region) of the first transistor 370. In addition, the first region 120A is a region sandwiched between the first terminal 108 and the second terminal 110 and is a region where the semiconductor film 112 overlaps the gate electrode 354 and the second gate insulating film 114. The first region 120A also functions as an active region (channel region) of the second transistor 350. The first region 120A of the first transistor 370 overlaps the first region 120A of the second transistor 350 in a plan view and cross-sectional view, and a longitudinal position parallel to the first axis D1 of the first region 120A of the first transistor 370 is the same as or substantially the same as a longitudinal position parallel to the first axis D1 of the first region 120A of the second transistor 350 in a plan view and cross-sectional view.

That is, the channel region of the first transistor 370 is the same as the channel region of the second transistor 350. On the other hand, The first terminal 108 is electrically diode-connected to the gate electrode 374, the first terminal 108 is a source electrode 372 of the first transistor 370 in the first rectifier circuit 306, and the second terminal 110 is a drain electrode 376 of the first transistor 370 in the first rectifier circuit 306. In addition, the second terminal 110 is electrically diode-connected to the gate electrode 354, the second terminal 110 is a source electrode 352 of the second transistor 350 in the second rectifier circuit 304, and the first terminal 108 is a drain electrode 356 of the second transistor 350 in the second rectifier circuit 304.

When a voltage is applied to the gate electrode 374, the first terminal 108, and the second terminal 110 of the first transistor 370, a current flows through the semiconductor film 112 of the first transistor 370. In addition, when a voltage is applied to the gate electrode 354, the second terminal 110, and the first terminal 108 of the second transistor 350, a current flows through the semiconductor film 112 of the second transistor 350.

For the third axis D3, the first rectifier circuit 306 (the first transistor 370) is arranged (stacked) on the second rectifier circuit 304 (the second transistor 350) and the first rectifier circuit 306 (the first transistor 370) is arranged closer to the first substrate 102 than the second rectifier circuit 304 (the second transistor 350).

For example, in the case where the first rectifier circuit is not arranged (stacked) on the second rectifier circuit 304, the transistors of the first rectifier circuit and the second rectifier circuit 304 constituting the semiconductor device 100 are formed on a plane including the first axis D1 and the second axis D2. In this case, an area of the transistors of the first rectifier circuit 306 and the second rectifier circuit 304 constituting the semiconductor device 100 are larger in the plane including the first axis D1 and the second axis D2, and the circuit scale of the semiconductor device 100 is larger than in the case where the first rectifier circuit is arranged (stacked) on the second rectifier circuit 304.

The first rectifier circuit 306 is arranged (stacked) on the second rectifier circuit 304 in the semiconductor device 100 according to the present embodiment. Therefore, the transistor size of the semiconductor device 100 can be smaller and the circuit scale of the semiconductor device 100 can be smaller than in the case where the first rectifier circuit 306 is not arranged (stacked) on the second rectifier circuit 304.

In addition, the gate electrode 374 and the source electrode 372 of the first transistor 370 are electrically connected to the drain electrode 356 of the second transistor 350, and the gate electrode 354 and the source electrode 352 of the second transistor 350 are electrically connected to the drain electrode 376 of the first transistor 370, as shown in FIG. 1A, FIG. 1B, FIG. 2A, and FIG. 2B.

That is, the gate electrode 374 and the source electrode 372 of the first transistor 370 function as an anode of the first rectifier circuit 306, and the drain electrode 376 of the first transistor 370 functions as a cathode of the first rectifier circuit 306. Therefore, the semiconductor device 100 can function as a bi-directional diode.

As shown in FIG. 2A and FIG. 2B, the gate electrode 374 and the source electrode 372 of the first transistor 370 and the drain electrode 356 of the second transistor 350 are electrically connected to an input terminal IN, and the gate electrode 354 and the source electrode 352 of the second transistor 350 and the drain electrode 376 of the first transistor 370 are electrically connected to an output terminal OUT, in the semiconductor device 100 according to an embodiment of the present invention. In addition, the gate electrode 374 and the source electrode 372 of the first transistor 370 and the drain electrode 356 of the second transistor 350 may be electrically connected to the output terminal OUT, and the gate electrode 354 and the source electrode 352 of the second transistor 350 and the drain electrode 376 of the first transistor 370 may be electrically connected to the input terminal IN, in the semiconductor device 100.

For example, when surges or ESD greater than the voltage supplied to the cathode of the first rectifier circuit 306 (the drain electrode 376 of the first transistor 370) enter the input terminal IN of the semiconductor device 100, a current flows from the anode of the first rectifier circuit 306 (the gate electrode 374 and the source electrode 372 of the first transistor 370) to the cathode of the first rectifier circuit 306. For example, impedances of a transistor, a resistance, a capacitance, or a circuit including these components electrically connected to the input terminal IN are greater than the semiconductor device 100. As a result, surges or ESD that have entered the input terminal IN of the semiconductor device 100 are unlikely to enter the transistor, the resistance, the capacitance, or the circuit including these electrically connected elements to the input terminal IN. In this case, the voltage supplied to an anode of the second rectifier circuit 304 (the gate electrode 354 and the source electrode 352 of the second transistor 350) is smaller than the voltage of the surges or ESD that have entered the input terminal IN. Therefore, no current flows from the anode of the second rectifier circuit 304 to a cathode of the second rectifier circuit 304 (the drain electrode 356 of the second transistor 350).

For example, when surges or ESD smaller than the voltage supplied to the anode of the second rectifier circuit 304 (the gate electrode 354 of the second transistor 350 and the source electrode 352) enter the input terminal IN of the semiconductor device 100, a current flows from the anode of the second rectifier circuit 304 to the cathode of the second rectifier circuit 304 (the drain electrode 356 of the second transistor 350). For example, impedances of the transistor, the resistance, the capacitance, or the circuit including these electrically connected to the input terminal IN are greater than the semiconductor device 100. As a result, surges or ESD that have entered the input terminal IN of the semiconductor device 100 are relaxed from entering the transistor, the resistance, the capacitance, or the circuit including these components—electrically connected to the input terminal IN. In this case, the voltage supplied to the anode of the first rectifier circuit 306 (the gate electrode 374 and the source electrode 372 of the first transistor 370) is smaller than the voltage supplied to the cathode of the first rectifier circuit 306 (the drain electrode 376 of the first transistor 370). Therefore, no current flows from the anode of the first rectifier circuit 306 to the cathode of the first rectifier circuit 306.

Therefore, using the semiconductor device 100 makes it possible to suppress the electrostatic breakdown of the transistor, the resistance, the capacitor, or the circuit including these components electrically connected to the input terminal IN.

### [1-2. Configuration of Display Device 20 Including Semiconductor Device 100]

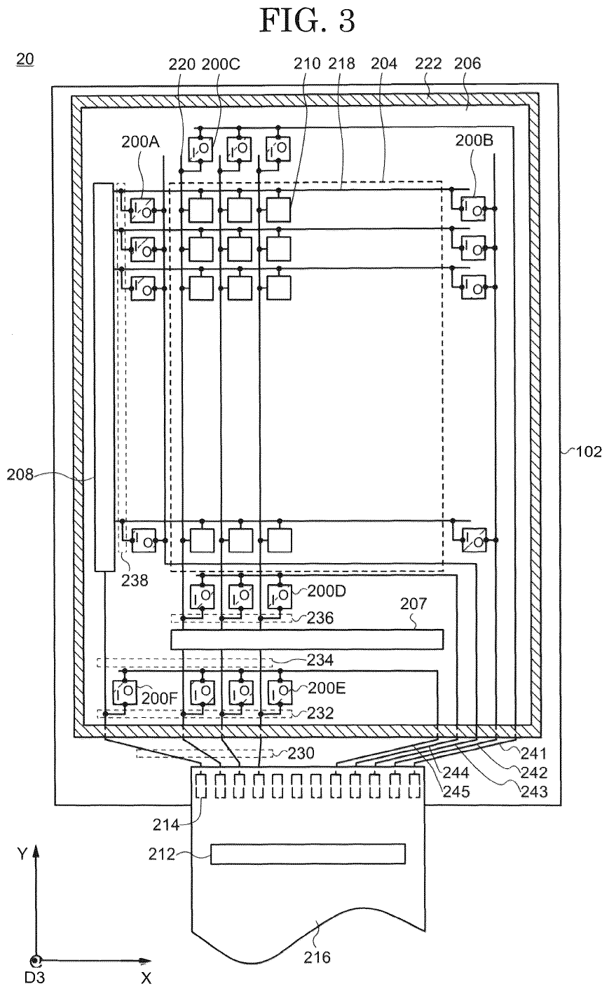

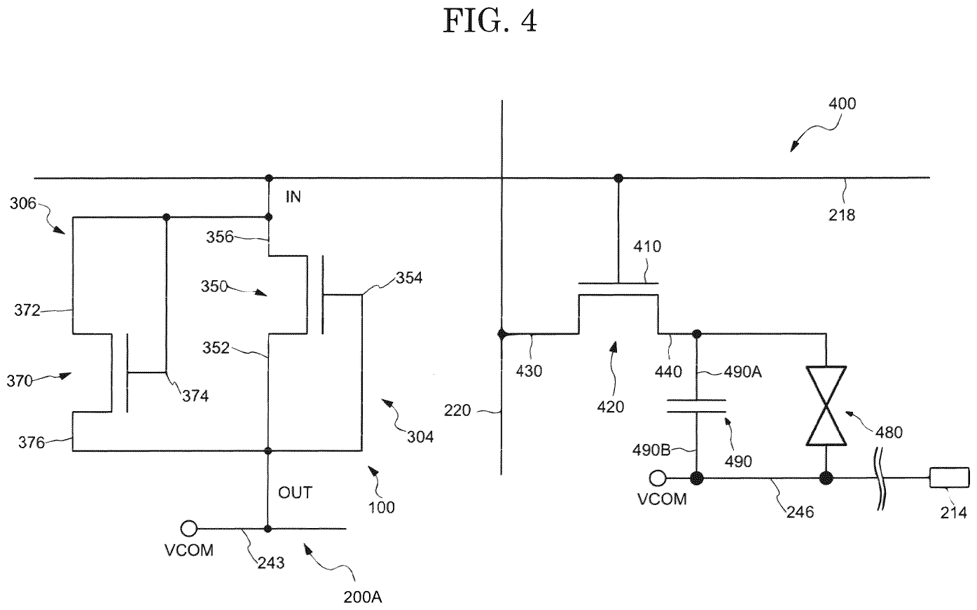

FIG. 3 is a plan view showing a configuration of the display device 20 according to an embodiment of the present invention. FIG. 4 is a circuit diagram showing a configuration of a protection circuit 200 including the semiconductor device 100 and a pixel circuit 400 according to an embodiment of the present invention. FIG. 5 is an end portion cross-sectional view showing a configuration of the protection circuit 200 including the semiconductor device 100 and the pixel circuit 400 according to an embodiment of the present invention. The configuration of the display device 20 is not limited to the configurations shown in FIG. 3 to FIG. 5. Descriptions of the same or similar configurations as those in FIG. 1A, FIG. 1B, FIG. 2A and FIG. 2B may be omitted in the configurations shown in FIG. 3 to FIG. 5.

For example, as shown in FIG. 3, the display device 20 includes a plurality of protection circuits 200A, 200B, 200C, 200D, 200E, and 200F, a display section 204 formed on an insulating surface, a peripheral section 206, a data line drive circuit 207, a scanning line drive circuit 208, a driver IC 212, a terminal section in which a plurality of terminals 214 is arranged, a flexible printed circuit board 216, and a seal portion 222. For example, the display device 20 according to the present embodiment is a liquid crystal display device using a liquid crystal element 480. The display device 20 according to the present embodiment may be a display device using an electrophoretic layer or a display device using a light-emitting element which is an EL element.

The peripheral section 206 surrounds the display section 204. The peripheral section 206 includes the plurality of protection circuits 200, the display section 204 formed on the insulating surface, the data line drive circuit 207, the scanning line drive circuit 208, the driver IC 212, the terminal section in which the plurality of terminals 214 is arranged, the flexible printed circuit board 216, and the seal portion 222. An array substrate 30 and a counter substrate 40 are bonded together by the seal portion 222. Although details will be described later, the plurality of protection circuits 200A, 200B, 200C, 200D, 200E, and 200F includes the semiconductor device 100.

Although the driver IC 212 is arranged in a COF (Chip on Film) method on the flexible printed circuit board 216, the arrangement of the driver IC 212 is not limited to the example shown here. The driver IC 212 may be arranged on the first substrate 102. The flexible printed circuit board 216 is electrically connected to the terminal section in which the plurality of terminals 214 arranged in the peripheral section 206 is arranged.

The plurality of protection circuits 200A is arranged between the scanning line drive circuit 208 and a plurality of scanning lines 218, and an input terminal IN (I) of the plurality of protection circuits 200A is electrically connected between the scanning line drive circuit 208 and the plurality of scanning lines 218. An output terminal OUT (O) of the plurality of protection circuits 200A is electrically connected to a wiring 243. The wiring 243 is electrically connected to the terminal 214. The scanning line drive circuit 208 is connected to the plurality of protection circuits 200A using a plurality of wirings 238. The plurality of protection circuits 200A is electrically connected to the plurality of scanning lines 218 on a one-to-one basis.

An end portion opposite to an end portion in which the plurality of protection circuits 200A is arranged is electrically connected to an input terminal IN (I) of the plurality of protection circuits 200B on a one-to-one basis in the plurality of scanning lines 218. An output terminal OUT (O) of the plurality of protection circuits 200B is electrically connected to a wiring 242. The wiring 242 is electrically connected to the terminal 214. The plurality of scanning lines 218 is arranged to extend parallel or substantially parallel to the X-axis of the display device 20.

The plurality of protection circuits 200D is arranged between the data line drive circuit 207 and a plurality of data lines 220, and an input terminal IN (I) of the plurality of protection circuits 200D is electrically connected between the data line drive circuit 207 and the plurality of data lines 220. An output terminal OUT (O) of the plurality of protection circuits 200D is electrically connected to a wiring 244. The wiring 244 is electrically connected to the terminal 214. The data line drive circuit 207 is connected to the plurality of protection circuits 200D using a plurality of wirings 236. The plurality of protection circuits 200D is electrically connected to the plurality of data lines 220 in a one-to-one manner.

An end portion opposed to an end portion in which the plurality of protection circuits 200D is arranged is electrically connected to an input terminal IN (I) of the plurality of protection circuits 200C on a one-to-one basis in the plurality of data lines 220. The output terminal OUT (O) of the plurality of protection circuits 200D is electrically connected to a wiring 241. The wiring 241 is electrically connected to the terminal 214. The plurality of data lines 220 is arranged to extend parallel or substantially parallel to the Y-axis of the display device 20.

For example, in the present embodiment, the plane including the X-axis and the Y-axis (X-Y plane) may be a D1-D2 plane, the X-axis may be a D1 axis, and the Y-axis may be a D2 axis. In addition, an axis perpendicular or substantially perpendicular to the X-Y plane may be the third axis D3.

The plurality of protection circuits 200E is arranged between the plurality of terminals 214 and the data line drive circuit 207, and an input terminal IN (I) of the plurality of protection circuits 200E is electrically connected between the plurality of terminals 214 and the data line drive circuit 207. An output terminal OUT (O) of the plurality of protection circuits 200E is electrically connected to a wiring 245. The wiring 245 is electrically connected to the terminal 214. The data line drive circuit 207 is electrically connected to the plurality of protection circuits 200E at 1:1 using a plurality of wirings 234. Each of the plurality of terminals 214 is electrically connected to the plurality of protection circuits 200E at 1:1 using a plurality of wirings 230 and a plurality of wirings 232. The plurality of wirings 230 and the plurality of wirings 232 may be electrically connected at 1:1, and the plurality of wirings 230 may be the plurality of wirings 232.

The plurality of protection circuits 200F is arranged between the plurality of terminals 214 and the scanning line drive circuit 208, and an input terminal IN (input terminal I) of the plurality of protection circuits 200F is electrically connected between the plurality of terminals 214 and the scanning line drive circuit 208. An output terminal OUT (output terminal O) of the plurality of protection circuits 200F is electrically connected to the wiring 245. The wiring 245 is electrically connected to the terminal 214. Each of the plurality of terminals 214 electrically connected to the scanning line drive circuit 208 is electrically connected to the plurality of protection circuits 200F at 1:1 using the plurality of wirings 230 and the plurality of wirings 232. One protection circuit 200F among the plurality of protection circuits 200F is shown as an example in the present embodiment.

For example, a common voltage VCOM (see FIG. 4) is supplied to the output terminal OUT (O) of the plurality of protection circuits 200A and the wiring 243 from the terminal 214. The common voltage VCOM (see FIG. 4) is supplied to the output terminal OUT (O) of the plurality of protection circuits 200B and the wiring 242 from the terminal 214. The common voltage VCOM (see FIG. 4) is supplied to an output terminal OUT (O) of the plurality of protection circuits 200C and the wiring 241 from the terminal 214. The common voltage VCOM (see FIG. 4) is supplied to the output terminal OUT (O) of the plurality of protection circuits 200D and the wiring 244 from the terminal 214. The common voltage VCOM (see FIG. 4) is supplied to the output terminal OUT (O) of the plurality of protection circuits 200E, the output terminal OUT (O) of the plurality of protection circuits 200F, and the wiring 245 from the terminal 214. Although the common voltage VCOM (see FIG. 4) is supplied to each of the plurality of protection circuits 200A to 200E using different wirings in the present embodiment, each of the plurality of protection circuits 200A to 200E may be electrically connected to the same wiring (for example, the wiring 241) and the common voltage VCOM may be supplied from the same wiring.

The driver IC 212 is electrically connected to the plurality of terminals 214. The driver IC 212 functions as a control unit for supplying a signal to the scanning line drive circuit 208 and data line drive circuit 207. For example, the driver IC 212 may include a circuit including the function of the data line drive circuit 207 other than a sampling switch, the data line drive circuit 207 may include a sampling switch (not shown), and the driver IC 212 may include the data line drive circuit 207. Part of the driver IC 212, the scanning line drive circuit 208, and the data line drive circuit 207 may be referred to as a control circuit in this embodiment, and the driver IC 212, the scanning line drive circuit 208, and the data line drive circuit 207 may be collectively referred to as a control circuit.

The insulating surface is a surface of the first substrate 102 in this embodiment. The first substrate 102 supports each layer constituting the transistor, the liquid crystal element, and the like arranged on the first substrate 102. The first substrate 102 itself may be made of an insulating material, the surface of the first substrate 102 itself may be the insulating surface, and a surface of an insulating film separately formed on the first substrate 102 may be the insulating surface. The material of the first substrate 102 and the material forming the insulating film are not particularly limited as long as the insulating surface can be obtained.

A plurality of pixels 210 is arranged in the display section 204 in a matrix parallel or substantially parallel to the X-axis and the Y-axis. Each of the plurality of pixels 210 includes the pixel circuit 400 (see FIG. 4).

For example, the arrangement of the plurality of pixels 210 is a stripe arrangement. For example, each of the plurality of pixels 210 may correspond to a sub-pixel R, a sub-pixel G, and a sub-pixel B. One pixel may be formed by three sub-pixels. A display element and the pixel circuit 400 are arranged in each of the sub-pixels. For example, the display element is the liquid crystal element 480. The color corresponding to the sub-pixel is determined by the characteristics of the liquid crystal element 480 or a color filter (not shown) arranged on the sub-pixel.

The sub-pixel R, the sub-pixel G, and the sub-pixel B can be configured to give different colors in the stripe arrangement. For example, a color filter layer that emits three primary colors of red, green, and blue may be arranged in each of the sub-pixel R, the sub-pixel G, and the sub-pixel B.

Each of the plurality of pixels 210 is electrically connected to the corresponding scanning line 218 and the corresponding data line 220. In addition, the plurality of pixels 210 may be electrically connected to a power supply line that supplies power. Although details will be described later, any element may be used as the element constituting the pixel circuit 400 as long as it is an element having a current control function.

For example, the driver IC 212 outputs a scanning signal to the scanning line 218 via the scanning line drive circuit 208. The driver IC 212 outputs a data signal corresponding to the data (image data) of the image displayed on the display section 204 to the data line 220. In addition, the driver IC 212 supplies voltages to the scanning line drive circuit 208, the pixel circuit 400, and the power supply line. In the case where the voltage, the scanning signal, and the data signal are input from the driver IC 212 to the pixel circuit included in the plurality of pixels 210, a transistor 420 (see FIG. 4) included in the pixel circuit 400 can supply a voltage corresponding to the image data to a pixel electrode 490A of the liquid crystal element 480 using the voltage, the scanning signal, and the data signal. As a result, each of the plurality of pixels 210 can display a color and an image corresponding to the data signal. Each of the scanning line 218 and the data line 220 may be referred to as a signal line in the present embodiment.

The plurality of protection circuits 200 including the semiconductor device 100 is arranged between each circuit and each signal line of the present embodiment, and between the terminal 214 and each circuit, and the like of the present embodiment. Surges or ESD entering the terminal 214, each circuit, or the signal line are relaxed, and the electrostatic breakdown of the terminal 214, each circuit, or the signal line is suppressed by using the protection circuit 200 including the semiconductor device 100. Further, an area where the protection circuit 200 is formed can be reduced by using the configuration of the semiconductor device 100 in the protection circuit 200. In addition, the protection circuit 200 using the semiconductor device 100 is applied to a high-definition display device and a narrow-frame display device with an increased number of signal lines. As a result, it is possible to sufficiently suppress the electrostatic damage to the display device while suppressing the increase in the frame width (the peripheral section 206) of the display device.

Although the example in which the plurality of protection circuits 200 including the semiconductor device 100 is arranged between the circuit of the present embodiment and each signal line, between the terminal 214 and each circuit, and the like is shown in the present embodiment, the arrangement of the plurality of protection circuits 200 including the semiconductor device 100 is not limited to the arrangement described here. For example, the protection circuit 200 including the semiconductor device 100 in the display device 20 may be arranged only between the scanning line drive circuit 208 and the plurality of scanning lines 218, and may be arranged at two locations between the scanning line drive circuit 208 and the plurality of scanning lines 218 and between the data line drive circuit 207 and the plurality of data lines 220. For example, the protection circuit 200 including the semiconductor device 100 in the display device 20 may be arranged at three locations between the scanning line drive circuit 208 and the plurality of scanning lines 218, between the data line drive circuit 207 and the plurality of data lines 220, and between the plurality of terminals 214 and each wiring, and may be arranged at four or more locations. The arrangement of the plurality of protection circuits 200 including the semiconductor device 100 may be appropriately set depending on the purpose, specifications, and the like of the display device 20.

FIG. 4 is a diagram showing an example in which the protection circuit 200A is arranged between the scanning line drive circuit 208 and the scanning line 218 and is electrically connected to the pixel circuit 400 constituting the pixel 210, in the display device 20 shown in FIG. 3.

The protection circuit 200A including one semiconductor device 100 is shown as an example in FIG. 4. The input terminal I of the protection circuit 200A (see FIG. 3) is electrically connected to the scanning line 218 and the input terminal IN of the semiconductor device 100, and the output terminal O of the protection circuit 200A (see FIG. 3) is electrically connected to an output terminal OUT of the semiconductor device 100. The output terminal O of the protection circuit 200A is electrically connected to the wiring 243 (see FIG. 3) and the common voltage VCOM is supplied from the terminal 214. Since the configuration of the semiconductor device 100 is the same as that of FIG. 1A, FIG. 1B, FIG. 2A and FIG. 2B, descriptions thereof will be omitted here.

A plurality of semiconductor devices 100 may be connected in series in the protection circuit 200A. Using the plurality of semiconductor devices 100 makes it possible to further increase the resistance value between a scanning line 180 and the wiring 243. Therefore, using protection circuit 200 including the semiconductor device 100 suppresses the electrostatic breakdown of the pixel circuit 400 and suppresses a leakage current to the wiring 243.

For example, the pixel circuit 400 includes the transistor 420, the liquid crystal element 480, and a capacitive element 490. The transistor 420 includes a gate electrode 410, a source electrode 430, and a drain electrode 440. The gate electrode 410 is electrically connected to the scanning line 218. The source electrode 430 is electrically connected to the data line 220. The drain electrode 440 is electrically connected to the pixel electrode 490A. The liquid crystal element 480 and the capacitive element 490 are electrically connected between the pixel electrode 490A and a common electrode 490B. For example, the common electrode 490B is electrically connected to the terminal 214 using a wiring 246 and is supplied with the common voltage VCOM.

FIG. 5 is an end portion cross-sectional view of part of the protection circuit 200A and the pixel circuit 400 including the semiconductor device 100 shown in FIG. 4. The display device 20 includes the semiconductor device 100 and the pixel circuit 400 including the semiconductor film 112 formed on the same substrate using the same material.

Since the configuration of the semiconductor device 100 is the same as that shown in FIG. 1B, descriptions thereof will be omitted. Here, the configuration of the pixel circuit 400 and the layers or films arranged above the second gate electrode layer 116 of the semiconductor device 100 will be mainly described.

The first transistor 370 is a bottom-gate transistor containing metal oxide as a material for forming the semiconductor film 112. The second transistor 350 is a top-gate transistor containing metal oxide as a material for forming the semiconductor film 112. The transistor 420 included in the pixel circuit 400 is a bottom-gate transistor containing metal oxide as a material for forming a semiconductor film 112B. For example, the data line drive circuit 207 or the scanning line drive circuit 208 may be configured using a transistor of a similar structure to the transistor described herein.

For example, the material for forming the semiconductor film 112 may include a Group 14 element such as silicon or germanium, and may include metal oxide. For example, the material containing silicon includes amorphous silicon and polycrystalline silicon. The metal oxide may include a Group 13 element such as indium or gallium, for example, a mixed oxide (IGO) of indium and gallium, a mixed oxide (IGZO) containing indium, gallium, and zinc. In addition, the metal oxide may include tin, titanium, zirconium, and the like. The metal oxide is referred to as an oxide semiconductor in the present embodiment.

The transistor 420 is a transistor formed in the first substrate 102. The gate electrode 410 is arranged on the first substrate 102. The gate electrode 410 is electrically connected to the gate electrode 374 and the scanning line 218 and is formed using the first gate electrode layer 104. A plurality of insulating layers may be arranged as an under layer between the first substrate 102 and the first gate electrode layer 104. The semiconductor film 112B is arranged above the gate electrode 410. The gate electrode 410 faces the semiconductor film 112B. The semiconductor film 112B is arranged in the same layer as the semiconductor film 112. The first gate insulating film 106 is arranged between the gate electrode 410 and the semiconductor film 112B. The gate insulating film in the transistor 420 is the first gate insulating film 106. A first terminal 109 functioning as the source electrode 430 is arranged on one end portion of a pattern of the semiconductor film 112B, and a second terminal 111 functioning as the drain electrode 440 is arranged on the other end portion of the pattern of the semiconductor film 112B. The source electrode 430 and the drain electrode 440 are electrically connected to the semiconductor film 112B on the upper surface and the side surface of the semiconductor film 112B, respectively. The first terminal 109 and the second terminal 111 are arranged in the same layer as the first terminal 108 and the second terminal 110. The second gate insulating film 114 is arranged in contact with part of the top and side surfaces of the semiconductor film 112B, part of the top and side surfaces of the first terminal 109, and part of the top and side surfaces of the second terminal 111.

An insulating film 316 is arranged so as to be in contact with the gate electrode 354 arranged in the second gate electrode layer 116 and the second gate insulating film 114. An insulating film 128 is arranged so as to be in contact with the gate electrode 354 arranged in the second gate electrode layer 116 and the second gate insulating film 114. The insulating film 128 is arranged on the insulating film 316. A contact hole 126 is formed in the insulating film 316 and the insulating film 128. The pixel electrode 490A is arranged on the insulating film 128 and inside the contact hole 126 by using a pixel electrode layer 130. The pixel electrode 490A is electrically connected to the second terminal 111 functioning as the drain electrode 440. A first alignment film 132 is arranged on the pixel electrode layer 130. For example, a part including the first substrate 102 to the first alignment film 132 parallel to the third axis D3 is referred to as the array substrate 30, in the present embodiment.

A counter electrode layer 138 is arranged on a surface of a second substrate 140 on which the first substrate 102 is arranged, and a second alignment film 136 is arranged on a surface of the counter electrode layer 138 on which the first substrate 102 is arranged, in a cross-sectional view. For example, a part including the second substrate 140, the counter electrode layer 138, and the second alignment film 136 parallel to the third axis D3 is referred to as the counter substrate 40, in the present embodiment.

The first alignment film 132 of the array substrate 30 and the first alignment film 132 of the array substrate 30 are bonded to each other at the seal portion 222 (see FIG. 3) so as to face each other in the display device 20. In addition, a liquid crystal layer 134 containing the liquid crystal element 480 is implanted between the first alignment film 132 of the array substrate 30 and the first alignment film 132 of the array substrate 30, in the display device 20.

An electric field is formed between the pixel electrode 490A and the counter electrode layer 138 when a voltage is supplied between the pixel electrode 490A and the counter electrode layer 138. The electric field causes the liquid crystal element 480 to operate, thereby displaying a color and an image corresponding to the data signal supplied to the pixel circuit 400.

A leakage current of TFT, where the metal oxide is used as the material for forming the semiconductor film, is extremely small, and the TFT is used as a switching element of the pixel circuit of the display device. As a result, electric charges accumulated in the capacitive element included in the pixel circuit can be held for a long time, so that a desired voltage can be maintained for a long time. On the other hand, since the leakage current of the TFT is extremely small, for example, surges or ESD that enter the terminal 214, each circuit, or each signal line are unlikely to be removed, and the TFT may be electrostatically destroyed. A protection circuit (for example, a protection diode) is well known as a circuit for protecting from surges or ESD. However, in order to perform a desired operation, it is a possibility that a circuit scale/size of the protection circuit becomes large.

The display device 20 according to the present embodiment includes the protection circuit 200 having the TFT using metal oxide as a material for forming the semiconductor film. In addition, the protection circuit 200 includes the first rectifier circuit 306 arranged (stacked) on the second rectifier circuit 304. As a result, the transistor size of the semiconductor device 100 can be reduced and the circuit scale can be reduced. In addition, surges or ESD entering the terminal 214, each circuit, or each signal line can be relaxed, and the electrostatic breakdown of the terminal 214, each circuit, or each signal line can be suppressed by using the semiconductor device 100 according to the present embodiment.

The known techniques used in the technical field of the present invention can be adopted for the structures of the transistor, capacitive element, and resistance element, and the materials of films, layers, and parts forming the transistor, capacitive element, and resistance element. For example, the common electrode 490B shown in FIG. 4 may be the counter electrode layer 138 shown in FIG. 5. For example, the common electrode 490B shown in FIG. 4 is not limited to the counter electrode layer 138 shown in FIG. 5, and may be arranged between the insulating film 128 and the insulating film 316 to form the capacitive element 490 between the pixel electrode 490A and the common electrode 490B, and to drive the liquid crystal element 480 (the liquid crystal layer 134) by the lateral electric field. Further, in the transistor 420, the second gate electrode may be arranged between the insulating film 316 and the second gate insulating film 114 so as to overlap the semiconductor film 112B formed using the metal oxide and two gate electrodes may be arranged so as to sandwich the gate electrode 410 and the second gate electrode.

### Second Embodiment

A configuration of a semiconductor device 100B will be described in the second embodiment. In the semiconductor device 100B according to the second embodiment, a resistance element is added to the semiconductor device 100 according to the first embodiment. In the semiconductor device 100B according to the second embodiment, other points are the same as those of the semiconductor device 100 according to the first embodiment. Here, the differences from the semiconductor device 100 will be mainly described.

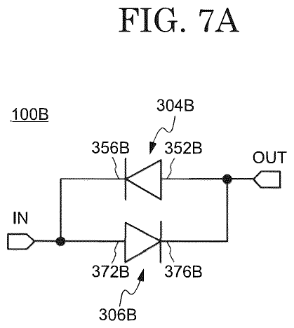

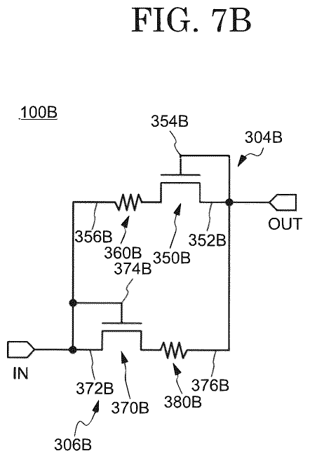

FIG. 6A is a plan view showing the configuration of the semiconductor device 100B, and FIG. 6B is an end portion cross-sectional view showing part of the cross-section taken along a line B1-B2 of the semiconductor device 100B shown in FIG. 6A. FIG. 7A and FIG. 7B are circuit diagrams showing a circuit configuration of the semiconductor device 100B. The configuration of the semiconductor device 100B is not limited to the configuration shown in FIG. 6A, FIG. 6B, FIG. 7A, and FIG. 7B. Descriptions of the same or similar configurations as those in FIG. 1A to FIG. 5 may be omitted in the configurations shown in FIG. 6A, FIG. 6B, FIG. 7A, and FIG. 7B.

In the semiconductor device 100B shown in FIG. 6A, FIG. 6B, FIG. 7A, and FIG. 7B, each of a first rectifier circuit 306B, a first transistor 370B, a gate electrode 374B, a drain electrode 372B, a second rectifier circuit 304B, a second transistor 350B, a gate electrode 354B, a source electrode 352B, and a drain electrode 356B corresponds to the first rectifier circuit 306, the first transistor 370, the gate electrode 374, the source electrode 372, the drain electrode 376, the second rectifier circuit 304, the second transistor 350, the gate electrode 354, the source electrode 352, and the drain electrode 356 of the semiconductor device 100 in the first embodiment.

As shown in FIG. 6A, FIG. 6B, FIG. 7A, or FIG. 7B, in a plan view or cross-sectional view of the first rectifier circuit 306B (the first transistor 370), a first region 120B sandwiched between the first terminal 108 electrically connected to the source electrode 372B and the gate electrode 374B can be defined by the arrangement of the gate electrode 374B, the first gate insulating film 106, the semiconductor film 112, the first terminal 108, the second terminal 110, the second gate insulating film 114, and the gate electrode 354B. The first region 120B functions as an active region (channel region) of the first transistor 370B in the semiconductor device 100B. A length of the first region 120B parallel to the first axis D1 is a length L2. The length L2 of the first region 120B may be longer or shorter than the length L1 of the first region 120A shown in FIG. 1A and FIG. 1B.

The first region 120B is sandwiched between the first terminal 108 and the second terminal 110, and the first region 120B is arranged on a side closer to the first terminal 108 than the second region 120C. In addition, the first region 120B is a region arranged between the second region 120C and the first terminal 108, wherein the semiconductor film 112 and the gate electrode 374B overlap.

In addition, a second region 120C sandwiched between the gate electrode 374B and the second terminal 110 electrically connected to the drain electrode 376B can be defined in the semiconductor film 112. A length of the second region 120C parallel to the first axis D1 is a length L3. The length L3 of the second region 120C is shorter than the length L2 of the first region 120B and the length L1 of the first region 120A.

The second region 120C is sandwiched between the first terminal 108 and the second terminal 110, and the second region 120C is arranged on a side closer to the second terminal 110 than the first region 120B. In addition, the second region 120C is a region arranged between the first region 120B and the second terminal 110 of the first transistor 370B and is a first resistance region where the semiconductor film 112 and the gate electrode 374B do not overlap. The first resistance region functions as a resistance element 380B. A resistance value of the resistance element 380B is greater than a resistance value of the first region 120B of the first transistor 370B.

In a plan view or cross-sectional view of the second rectifier circuit 304B (the second transistor 350B), a third region 120D sandwiched between the second terminal 110 electrically connected to the source electrode 352B and the gate electrode 354B can be defined in the semiconductor film 112 by the arrangement of the gate electrode 374B, the first gate insulating film 106, the semiconductor film 112, the first terminal 108, the second terminal 110, the second gate insulating film 114, and the gate electrode 354B. The third region 120D functions as an active region (channel region) of the second transistor 350B, in the semiconductor device 100B. A length of the third region 120D parallel to the first axis D1 is a length L4. The length L4 of the third region 120D is different from the length L1 of the first region 120A, and the length L4 may be longer or shorter than the length L1. The length L4 is equivalent or substantially equivalent to the length L2 of the first region 120B.

The third region 120D is sandwiched between the first terminal 108 and the second terminal 110, and the third region 120D is arranged on a side closer to the second terminal 110 than a fourth region 120E. In addition, the third region 120D is a region arranged between the fourth region 120E and the second terminal 110, wherein the semiconductor film 112 and the gate electrode 354B overlap. The third region 120D overlaps part of the first region 120B and the second region 120C in a plan view and cross-sectional view, and a position of the third region 120D in the longitudinal direction parallel to the first axis D1 is different from a position of the first region 120B in the longitudinal direction parallel to the first axis D1 in a plan view and cross-sectional view.

In addition, the fourth region 120E sandwiched between the gate electrode 354B and the first terminal 108 electrically connected to the drain electrode 356B can be defined in the semiconductor film 112. A length of the fourth region 120E parallel to the first axis D1 is a length L5. The length L5 of the fourth region 120E is shorter than the length L4 of the third region 120D, the length L2 of the first region 120B, and the length L1 of the first region 120A, and is equivalent to or substantially equivalent to the length L3 of the third region 120D.

The fourth region 120E is sandwiched between the first terminal 108 and the second terminal 110, and the fourth region 120E is arranged on a side closer to the first terminal 108 than the third region 120D. In addition, the fourth region 120E is a region arranged between the third region 120D of the second transistor 350B and the first terminal 108, and is a second resistance region where the semiconductor film 112 and the gate electrode 354B do not overlap. The second resistance region functions as a resistance element 360B. A resistance value of the resistance element 360B is greater than the resistance value of the third region 120D of the second transistor 350B.

Since the semiconductor device 100B includes that the second region 120C and the third region 120D are arranged in the second embodiment, the resistance values of the first transistor 370B and the second transistor 350B can be made larger than the resistance values of the first transistor 370 and the second transistor 350 according to the first embodiment. Therefore, for example, in the case where the resistance values of the first transistor 370B and the second transistor 350B are the same as or substantially the same as the resistance values of the first transistor 370 and the second transistor 350 according to the first embodiment, the length L2 and the length L4 can be made shorter than the length L1 according to the first embodiment. Therefore, the layout of the first transistor 370B and the second transistor 350B can be reduced from the layout of the first transistor 370 and the second transistor 350 according to the first embodiment. As a result, the size of the semiconductor device 100B can be reduced, the frame width (the peripheral section 206) can be reduced, and the narrow-frame display device can be realized. For example, in the case where a plurality of semiconductor devices 100B is connected in series, the resistance values of the first transistor 370B and the second transistor 350B per unit length can be increased by making the length L2 and the length L4 longer than the length L1 according to the first embodiment. Therefore, since the number of the plurality of semiconductor devices 100B connected in series can be reduced, the total area occupied by the semiconductor device 100B can be reduced. As a result, the frame width (the peripheral section 206) can be reduced, and the narrow-frame display device can be realized. Furthermore, similar to the semiconductor device 100, the use of the semiconductor device 100B can suppress the electrostatic breakdown of the transistor, the resistance, the capacitance, or the circuit including these components electrically connected to the input terminal IN. In addition, the first resistance region and the second resistance region are arranged between the input terminal IN and the output terminal OUT by using the semiconductor device 100B, and the resistance value between the input terminal IN and the output terminal OUT is further increased. As a result, for example, the leakage current to the wiring, the device, or the circuit arranged at the output terminal OUT is further suppressed.

### Third Embodiment

FIG. 8 is an end portion cross-sectional view showing a configuration of the protection circuit 200 and the pixel circuit 400 including the semiconductor device 100 of a display device 20B according to an embodiment of the present invention. Descriptions of the same or similar configurations as those in FIG. 1A to FIG. 7B may be omitted in the configuration shown in FIG. 8.

The display device 20B shown in FIG. 8 is a display device having the protection circuit 200A including the differently structured pixel circuit 400 and the semiconductor device 100 on the same substrate. The structure of the pixel circuit 400 is different from the structure of the semiconductor device 100. Since the protection circuit 200A including the pixel circuit 400 and the semiconductor device 100 has the same configuration as that of the first embodiment, detailed descriptions thereof will be omitted. Here, a configuration different from that of the first embodiment will be mainly described.

In the display device 20B, the first transistor 370 included in the semiconductor device 100 is a bottom-gate transistor containing polycrystalline silicon as a material for forming the semiconductor film 112, the second transistor 350 included in the semiconductor device 100 is a top-gate transistor containing polycrystalline silicon as a material for forming the semiconductor film 112, and the transistor 420 included in the pixel circuit 400 is a bottom-gate transistor containing metal oxide as a material for forming the semiconductor film 112B. For example, the data line drive circuit 207 or the scanning line drive circuit 208 may be configured using a transistor of a similar structure to the transistor described herein.

The first transistor 370 and the second transistor 350 are transistors stacked in this order from the first substrate 102 with respect to the third axis D3, and constitute the semiconductor device 100. The gate electrode 374 is formed using the first gate electrode layer 104 arranged to be in contact with the upper surface of the first substrate 102. The first gate insulating film 106 is in contact with the upper surface of the first substrate 102 and the first gate electrode layer 104 and is arranged to cover the upper surface and the side surface of the gate electrode 374. A plurality of insulating layers may be arranged as an under layer between the first substrate 102 and the first gate electrode layer 104. The semiconductor film 112 is arranged to be in contact with the first gate insulating film 106 and is formed to overlap the gate electrode 374. The second gate insulating film 114 is arranged in contact with part of the upper surface and the side surface of the semiconductor film 112. The gate electrode 354 is formed using the second gate electrode layer 116 arranged to be in contact with the upper surface of the second gate insulating film 114. In addition, the gate electrode 354 is formed to overlap the semiconductor film 112. An insulating film 310 is arranged on the gate electrode 354 in contact with part of the upper surface and the side surface of the gate electrode 354 and in contact with the upper surface of the second gate insulating film 114. An insulating film 312 is arranged on the insulating film 310 to be in contact with the upper surface of the insulating film 310. An insulating film 314 is arranged on the insulating film 312 to be in contact with the upper surface of the insulating film 312. The contact hole 121 is formed through the first gate insulating film 106, the second gate insulating film 114, the insulating film 310, the insulating film 312, and the insulating film 314, the contact holes 121B and 122 are formed through the second gate insulating film 114, the insulating film 310, the insulating film 312, and the insulating film 314, and the contact hole 122B is formed through the insulating film 310, the insulating film 312, and the insulating film 314. The first terminal 108 is arranged in contact with the upper surface of the insulating film 314, is electrically connected to the gate electrode 374 via the contact hole 121, and is electrically connected to the semiconductor film 112 via the contact hole 121B. In the first terminal 108, a portion electrically connected to the semiconductor film 112 via the contact hole 121B is the source electrode 372, and a portion electrically connected to the gate electrode 374 via the contact hole 121 is the drain electrode 356. The second terminal 110 is arranged in contact with the upper surface of the insulating film 314, is electrically connected to the gate electrode 354 via the contact hole 122B, and is electrically connected to the semiconductor film 112 via the contact hole 122B. In the second terminal 110, a portion electrically connected to the semiconductor film 112 via the contact hole 122 is the drain electrode 376, and a portion electrically connected to the gate electrode 354 via the contact hole 122B is the source electrode 352.

The transistor 420 is a transistor formed in the first substrate 102. The gate electrode 410 is arranged on the insulating film 310. The gate electrode 410 is electrically connected to the gate electrode 374, the source electrode 372, the drain electrode 356, and the scanning line 218. The gate electrode 410 may be formed of the same material as the first gate electrode layer 104 and may be formed of a material different from the first gate electrode layer 104. The semiconductor film 112B is arranged above the gate electrode 410. The gate electrode 410 faces the semiconductor film 112B. The insulating film 312 is arranged between the gate electrode 410 and the semiconductor film 112B. The gate insulating film in the transistor 420 is the insulating film 312. The first terminal 109 functioning as the source electrode 430 is arranged on one end portion of the pattern of the semiconductor film 112B, and the second terminal 111 functioning as the drain electrode 440 is arranged on the other end portion of the pattern of the semiconductor film 112B. The source electrode 430 and the drain electrode 440 are electrically connected to the semiconductor film 112B on the upper surface and the side surface of the semiconductor film 112B, respectively. The insulating film 314 is arranged to be in contact with part of the upper surface and the side surface of the semiconductor film 112B, part of the upper surface and the side surface of the first terminal 109, and part of the upper surface and the side surface of the second terminal 111. Contact holes 311 and 313 are opened in the insulating film 314. A first terminal 109B is arranged on the insulating film 314, and is electrically connected to the first terminal 109 via the contact hole 311. In addition, a second terminal 111B is arranged on the insulating film 314, and is electrically connected to the second terminal 111 via the contact hole 313. The first terminal 109B and the second terminal 111B are arranged in the same layer as the first terminal 108 and the second terminal 110.

The insulating film 316 is arranged on the first terminal 109B, the second terminal 111B, the first terminal 108, and the second terminal 110. Since the configuration above the insulating film 316 is similar to the configuration shown in FIG. 5 with respect to the third axis D3, detailed descriptions thereof will be omitted.

The pixel electrode 490A is electrically connected to the second terminal 111B via the contact hole 126 in the display device 20B according to the third embodiment. For example, in the display device 20B according to the third embodiment, a portion including the first substrate 102 to the first alignment film 132 parallel to the third axis D3 is referred to as an array substrate 30B, and a portion including the second substrate 140, the counter electrode layer 138, and the second alignment film 136 is referred to as a counter substrate 40B.

As in the case of using the semiconductor device 100 containing metal oxide as a material for forming the semiconductor film 112, even in the case of using the semiconductor device 100 containing polycrystalline silicon as a material for forming the semiconductor film 112, surges or ESD entering the terminal 214, each circuit, or each signal line can be relaxed, and the electrostatic breakdown of the terminal 214, each circuit, or each signal line can be suppressed.

### Fourth Embodiment

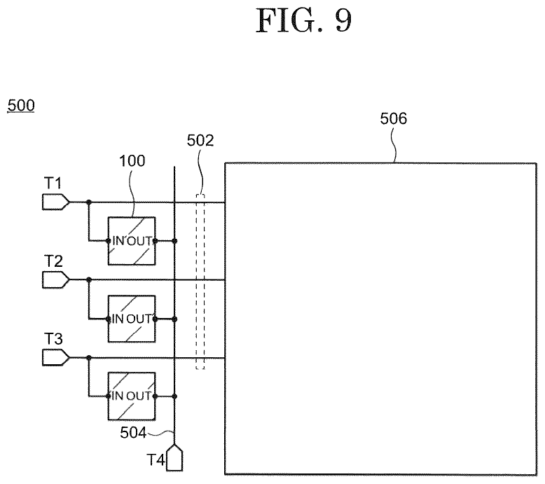

FIG. 9 is a plan view showing a configuration of a semiconductor integrated circuit 500 according to an embodiment of the present invention. Descriptions of the same or similar configurations as those in FIG. 1A to FIG. 8 may be omitted in the configuration shown in FIG. 9.

The semiconductor integrated circuit 500 includes at least the semiconductor device 100, a plurality of wirings 502, a wiring 504, and an electronic device 506. The input terminal IN (I) of the plurality of semiconductor devices 100 is electrically connected between terminals T1 to T3 electrically connected to each of the plurality of wirings 502 and the electronic device 506. The output terminal OUT (O) of the plurality of semiconductor devices 100 is electrically connected to a terminal T4 connected to the wiring 504. The semiconductor device 100 has the same configuration and function as the semiconductor device 100, the semiconductor device 100B, the protection circuit 200 including the semiconductor device 100 or the semiconductor device 100B described in any one of the first embodiment to the third embodiments. Since the configuration and function of the semiconductor device 100 are described in the first embodiment to the third embodiments, descriptions thereof will be omitted.

For example, a signal for controlling the electronic device 506 is supplied to the terminals T1 to T3. The signal includes a voltage. For example, a constant voltage is supplied to the terminal T4. For example, the constant voltage is a grounding voltage, 0 V, or VSS.

For example, the electronic device 506 is an analog circuit, a storage circuit, an arithmetic circuit, or a device including these components. For example, the analogue circuit is a backlight, an illumination device, an LED, a micro LED, or an amplifier circuit. For example, the storage circuit is a volatile memory such as a DRAM, SRAM, or a non-volatile memory. For example, the arithmetic circuit is a CPU.

Using the semiconductor integrated circuit 500 including the semiconductor device 100 makes it possible to relax surges or ESD entering the electronic device 506 included in the semiconductor integrated circuit 500 and suppress the electrostatic breakdown of the electronic device 506.

Embodiments of the protection circuit 200 including the semiconductor device 100, the display device 20 including the protection circuit 200, the display device 20B, or the semiconductor integrated circuit 500 described above as embodiments of the present invention can be appropriately combined and implemented as long as there is no mutual inconsistency. Within the spirit of the present invention, it is understood that various modifications and changes can be made by those skilled in the art and that these modifications and changes also fall within the scope of the present invention. For example, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first gate electrode;
a first gate insulating film arranged on the first gate electrode;
a semiconductor film arranged on the first gate insulating film and overlapping the first gate electrode;
a first terminal in contact with the semiconductor film and electrically connected to the semiconductor film and the first gate electrode;
a second terminal in contact with the semiconductor film and spaced apart from the first terminal;
a second gate insulating film arranged over the semiconductor film, the first terminal and the second terminal; and
a second gate electrode arranged on the second gate insulating film, overlapping the semiconductor film and electrically connected to the second terminal.

2. The semiconductor device according to claim 1, further comprising:
a first rectifier circuit; and
a second rectifier circuit,
wherein either one of the first rectifier circuit or the second rectifier circuit is a diode-connected first transistor,
the other of the first rectifier circuit or the second rectifier circuit is a diode-connected second transistor,
the first transistor includes the first gate electrode, the first gate insulating film, the semiconductor film, the first terminal and the second terminal, and
the second transistor includes the second gate electrode, the second gate insulating film, the semiconductor film, the first terminal and the second terminal.

3. The semiconductor device according to claim 2, wherein the first terminal is a source electrode in the first rectifier circuit,
the second terminal is a drain electrode in the first rectifier circuit,
the second terminal is a source electrode in the second rectifier circuit, and
the first terminal is a drain electrode in the second rectifier circuit.

4. The semiconductor device according to claim 2, wherein the semiconductor film includes a channel region of the first transistor and a channel region of the second transistor between the first terminal and the second terminal in a plan view,
the first gate insulating film overlaps the first gate electrode in the channel region of the first transistor, and
the second gate insulating film overlaps the second gate electrode in the channel region of the second transistor.

5. The semiconductor device according to claim 4, wherein a position of the channel region of the first transistor is the same as a position of the channel region of the second transistor.

6. The semiconductor device according to claim 4, wherein the semiconductor film includes a first resistance region in which the first gate electrode does not overlap between the channel region of the first transistor and the second terminal in a plan view, and a second resistance region in which the second gate electrode does not overlap between the channel region of the second transistor and the first terminal in a plan view.

7. The semiconductor device according to claim 6, wherein the position of the channel region of the first transistor is different from the position of the channel region of the second transistor.

8. The semiconductor device according to claim 7, wherein the semiconductor film includes amorphous silicon, polycrystalline silicon or metal oxide.

9. A display device comprising:
the semiconductor device according to claim 1;
a display section including a plurality of pixels electrically connected to the plurality of semiconductor devices; and
a control circuit electrically connected to the plurality of pixels and controlling the plurality of pixels.

10. The display device according to claim 9, wherein the control circuit is electrically connected to the semiconductor device.

11. A semiconductor integrated circuit comprising:
the semiconductor device according to claim 1, and
an electronic device electrically connected to the semiconductor device.
